(19) United States
(12) Patent Application Publication
(10) Pub. No.: US 2025/0199066 A1
(43) Pub. Date: Jun. 19, 2025

(54) TEST IMPLEMENTATION

(71) Applicant: STMicroelectronics International N.V., Geneva (CH)

(72) Inventor: Thomas SARNO, Fuveau (FR)

(21) Appl. No.: 18/967,975

(22) Filed: Dec. 4, 2024

(30) Foreign Application Priority Data
Dec. 19, 2023 (FR) FR2314454

(51) Int. Cl. G01R 31/3177; G01R 31/3185

(52) U.S. Cl. CPC G01R 31/3177; G01R 31/318516

(57) ABSTRACT

The present description provides a method of implementation of a test of comparison of a first data word with at least one second data word. An example method includes the following successive steps dividing the first data word into at least one portion; comparing each of the at least one portion of the first data word with at least one corresponding portion of the at least one second data word, by using, for each comparison, a first lookup table; and comparing the results of each of the first lookup tables by using a second lookup table.

### CROSS REFERENCE TO RELATED APPLICATION(S)

This application claims the priority benefit of French patent application number FR2314454, filed on Dec. 19, 2023, entitled “Mise en oeuvre d'un test”, which is hereby incorporated by reference to the maximum extent allowable by law.

### TECHNICAL FIELD

The present disclosure generally concerns electronic circuits and devices and the implementation of logic functions by these electronic circuits and devices. The present disclosure more particularly relates to the implementation of logic tests.

### BACKGROUND

To implement programs and software, it is common for electronic circuits and devices to use combinational logic functions. More particularly, logic tests are very often used.

It would be desirable to be able to improve, at least partly, certain aspects of the implementation of logic tests by electronic devices.

### BRIEF SUMMARY

There exists a need for an implementation of logic tests protected against data leakage.

There exists a need for an implementation of logic tests protected against side-channel attacks.

There exists a need for an implementation of logic tests protected against fault injection attacks.

There exists a need for electronic circuits and devices adapted to such implementations.

An embodiment overcomes all or part of the disadvantages of known implementations of tests.

An embodiment overcomes all or part of the disadvantages of known circuits and devices adapted to the implementation of logic tests.

An embodiment provides an implementation of logic tests using at least two cascaded lookup tables.

An embodiment provides a method of implementation of a test of comparison of a first data word with at least one second data word, comprising the following successive steps:
dividing the first data word into at least one portion;
comparing each of the at least one portion of the first data word with at least one corresponding portion of the at least one second data word, by using, for each comparison, a first lookup table;
comparing the results of each of the first lookup tables by using a second lookup table.

Another embodiment provides an electronic device adapted to implementing a test of comparison of a first data word with at least one second data word, comprising the following successive steps:
dividing the first data word into at least one portion;
comparing each of the at least one portion of the first data word with at least one corresponding portion of the at least one second data word, by using, for each comparison, a first lookup table;
comparing the results of each of the first lookup tables by using a second lookup table.

According to an embodiment, during the division step, the first data word is divided into at least one portion.

According to an embodiment, each result of the first lookup tables is a third binary word.

According to an embodiment, the third binary word comprises one bit.

According to an embodiment, the third binary word comprises at least two bits.

According to an embodiment, each of the at least two portions of the first binary word comprises at least two bits, and each of the at least one corresponding portion of the at least one second binary word comprises at least two bits.

According to an embodiment, the test is selected from the group comprising: a logic equality test, a logic “greater than”-type test, a logic “greater than or equal to”-type test, a logic “smaller than”-type test, a logic “smaller than or equal to”-type test, a logic “is between”-type test, a test of the divisibility of an integer by another integer, a logic test concerning the Hamming weight of binary data item, and any combination of one or a plurality of the above tests with one another.

According to an embodiment, the results of each of the first lookup tables are concatenated into a fourth data word to be compared by using the second lookup table.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows an embodiment of an electronic device adapted to executing an implementation mode of a method of implementation of logic tests;

FIG. 2 shows, very schematically and in the form of blocks, an implementation of a test;

FIG. 3 shows, very schematically and in the form of blocks, a first general example of an implementation mode of a method for implementing logic tests;

FIG. 4 shows, very schematically and in the form of blocks, a second practical example of an implementation mode of a method for implementing logic tests;

FIG. 5 shows, very schematically and in the form of blocks, a third practical example of an implementation mode of a method for implementing logic tests;

FIG. 6 shows, very schematically and in the form of blocks, a fourth practical example of an implementation mode of a method for implementing logic tests; and

FIG. 7 shows, very schematically and in the form of blocks, a fifth practical example of an implementation mode of a method for implementing logic tests.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

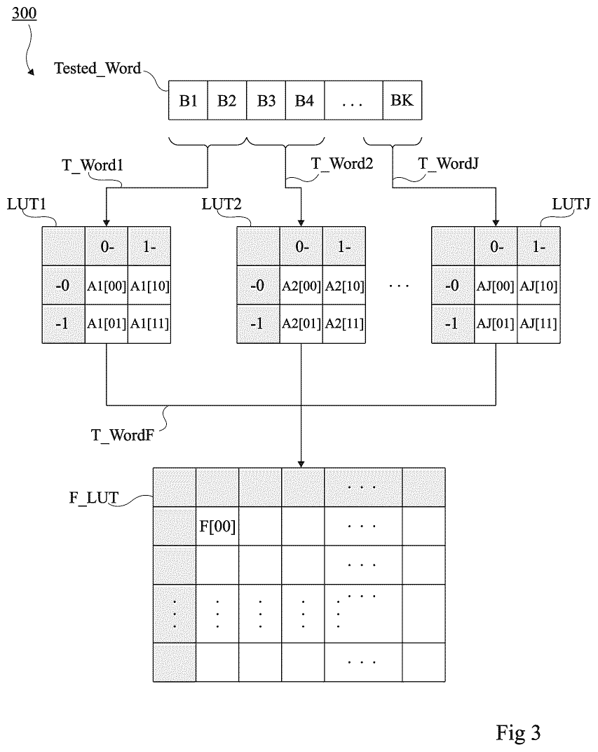

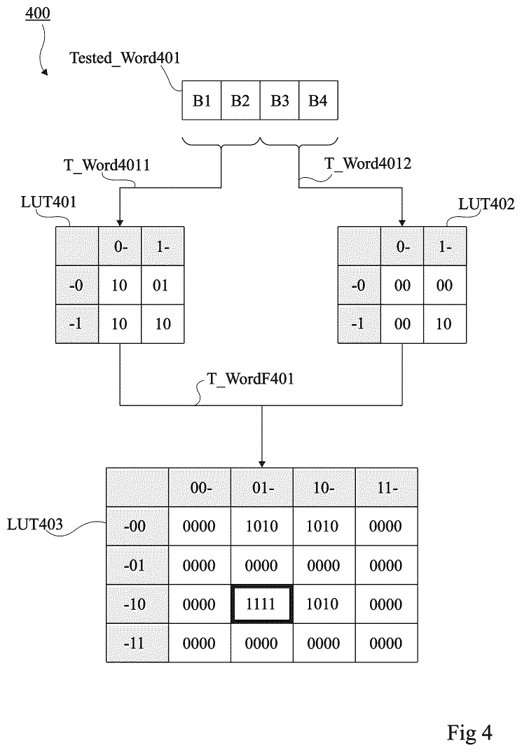

The embodiments described hereafter concern a more secure implementation of a test, such as a logic test or an arithmetic test, that is, an implementation of a test in which the data used are less likely to be captured by a third party, or an implementation of a test which is less vulnerable to side-channel attacks, and, in particular, to fault injection attacks. For this purpose, the implementation modes described hereafter are based on the use of at least two “stages” of lookup tables (LUTs). A general example of implementation is described in relation with FIG. 3, specific examples are described in relation with FIGS. 4 to 7.

Further, these embodiments can be applied to any electronic device implementing logic tests.

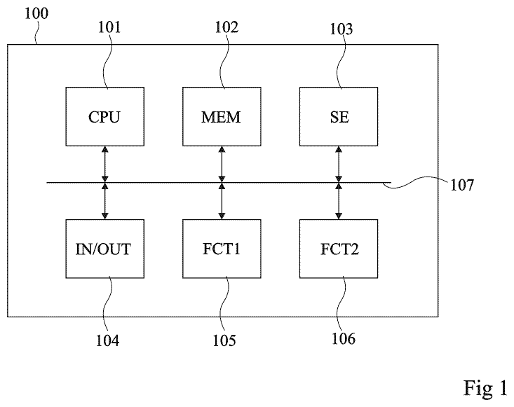

FIG. 1 is a block diagram, very schematically showing an architecture of an example of an electronic device 100 adapted to implementing one or a plurality of logic tests.

Electronic device 100 comprises a processor 101 (CPU) adapted to implementing different operations of processing of data stored in memories and/or supplied by other circuits of device 100. According to an embodiment, processor 101 is adapted to implementing one or a plurality of logic tests based on data that it receives.

Electronic device 100 further comprises different types of memories 102 (MEM), among which, for example, a non-volatile memory, a volatile memory, and/or a read-only memory. Each memory 102 may be adapted to storing different types of data.

In the following description, there is called data word a data item comprising a plurality of bits. A portion of a data word corresponds to one or a plurality of bits of this data word.

Electronic device 100 further comprises, for example, a secure element 103 (SE) adapted to processing critical and/or secret data. Secure element 103 may comprise its own processor(s), its own memory or memories, etc. According to an embodiment, secure element 101 may be adapted to implementing logic tests.

Electronic device 100 may further comprise interface circuits 104 (IN/OUT) adapted to sending and/or to receiving data from the outside of device 100. Interface circuits 104 may further be adapted to implementing a data display, for example, a display screen.

Electronic device 100 further comprises different circuits 105 (FCT1) and 106 (FCT2) adapted to carrying out different functions. As an example, circuits 105 and 106 may comprise measurement circuits, data conversion circuits, etc. According to an embodiment, circuits 105 and 106 may comprise a circuit adapted to implementing a matrix transposition method.

Electronic device 100 further comprises one or a plurality of data buses 107 adapted to transferring data between its different components.

According to a specific example, electronic device 100 is adapted to implementing computer programs, and in particular a computer program enabling to implement one or a plurality of logic tests.

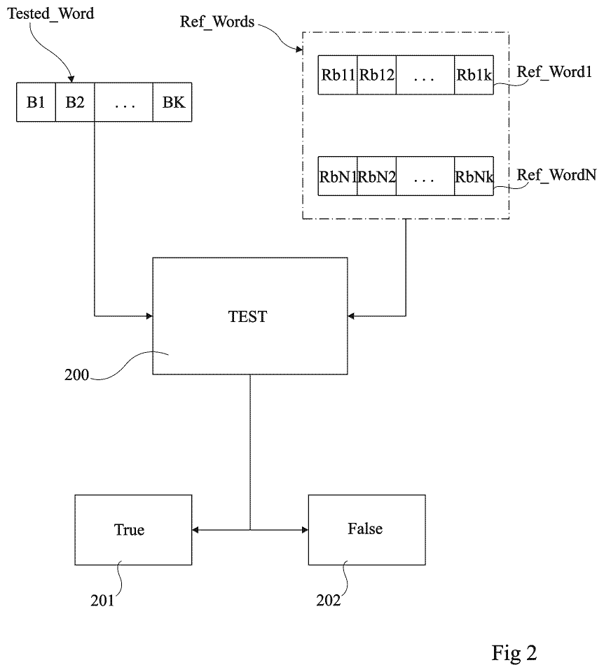

FIG. 2 shows, very schematically and in the form of blocks, the implementation of a test 200 (TEST).

Test 200 receives, as input, a data word Tested_Word to be tested and one or a plurality of comparison reference words Ref_Words.

According to an embodiment, test 200 enables, based on the data word to be tested Tested_Word, to carry out a binary function, the result of which may be a binary data item 201 (True) representing information TRUE or a binary data item 202 (False) representing information FALSE. There is here called binary data item a data item formed of one or a plurality of data bits.

According to an embodiment, test 200 enables to compare the data word to be tested Tested_Word with one or a plurality of reference data words selected from among reference words Ref_Words. According to an embodiment, test 200 may be a logic test or an arithmetic test. According to an example, test 200 may verify the equality of the data word to be tested Tested_Word with one or a plurality of reference data words selected from among the reference words Ref_Words. According to another example, test 200 may compare a numerical value represented by the data word to be tested Tested_Word with one or a plurality of reference data words selected from among the reference words Ref_Words. In other words, according to an embodiment, test 200 implements a binary function selected from the group comprising: a logic equality test, a logic “greater than”-type test, a logic “greater than or equal to”-type test, a logic “smaller than”-type test, a logic “is between”-type test, a test of the divisibility of an integer by another integer, a logic test concerning the Hamming weight of binary data, and any combination of one or a plurality of the above tests with one another. Generally, the list of the reference words Ref_Words may represent any property to be verified for word Tested_Word, including ad-hoc properties which are neither arithmetic properties nor logic properties, for example a test of “smaller than or equal to and different from N and divisible by K” type.

According to an embodiment, the data word to be tested Tested_Word is a binary word comprising K bits, K being a positive integer. According to a preferred embodiment, K is an integer greater than or equal to two. The bits of data word Tested_Word are referenced B1 to BK.

According to an embodiment, test 200 is adapted to receiving N reference data words Ref_Words, N being an integer greater than or equal to one. Each individual reference word is designated with reference Ref_Wordn, n being an integer varying from 1 to N. Each reference data word Ref_Word1, . . . , Ref_WordN is a binary word comprising K bits like the data word to be tested Tested_Word. The bits of each reference data word Ref_Wordn are designated with reference Rbn1 to RbnK.

FIG. 3 illustrates a method 300 for implementing the test 200 described in relation with FIG. 2, according to an embodiment.

To be implemented, method 300 uses lookup tables. More specifically, method 300 uses J primary lookup tables LUTj, J being a positive integer, preferably an integer greater than or equal to two, and j being an integer in the range from 1 to J, and at least one secondary lookup table F_LUT. The secondary lookup table F_LUT may also be called final lookup table. Practical examples of implementation of the method are described in relation with FIGS. 4 to 7.

To be implemented, method 300 begins with the step of division of the data word to be tested Tested_Word into J portions T_Word1 to T_WordJ. Each portion T_Wordj is a binary data item comprising at least one bit, preferably at least two bits. It is also spoken of a portion of order j to designate portion T_Wordj. It should be noted that the J portions may have different numbers of bits. In the example shown in FIG. 3, each portion T_Wordj is a binary data item comprising two bits.

According to an embodiment, when integer J is equal to one, the division step is a step of division into a single portion T_Word1 of the data word to be tested Tested_Word. This portion T_Word1 corresponds to the complete data word to be tested Tested_Word.

Then, a first step of comparison of each portion T_Wordj is carried out by implementing primary lookup table LUTj. Each lookup table LUTj has been generated to provide the result of the comparison of a binary data item of the type of a portion T_Wordj with the corresponding portions of reference data words Ref_Words. More particularly, to obtain lookup table LUTj, the reference data words Ref_Words are divided into J portions in the same way as the data word to be tested Tested_Word, that is, into J portions having the same number of bits as the J portions of the data word to be tested Tested_Word.

Each primary lookup table LUTj comprises 2\hat{ }NBits values, NBits being an integer representing the number of bits of the portion T_WordJ to be compared, illustrating all possible comparison results. “\hat{ }” here represents the mathematical operation power. In the case illustrated in FIG. 3, since all portions T_Wordj comprise two bits, each lookup table LUTj comprises four values divided into two rows and two columns. The values of lookup tables LUTj are designated with reference Aj[p; q], p being an integer representing the index of the column of the value and q being an integer representing the index of the row of the value.

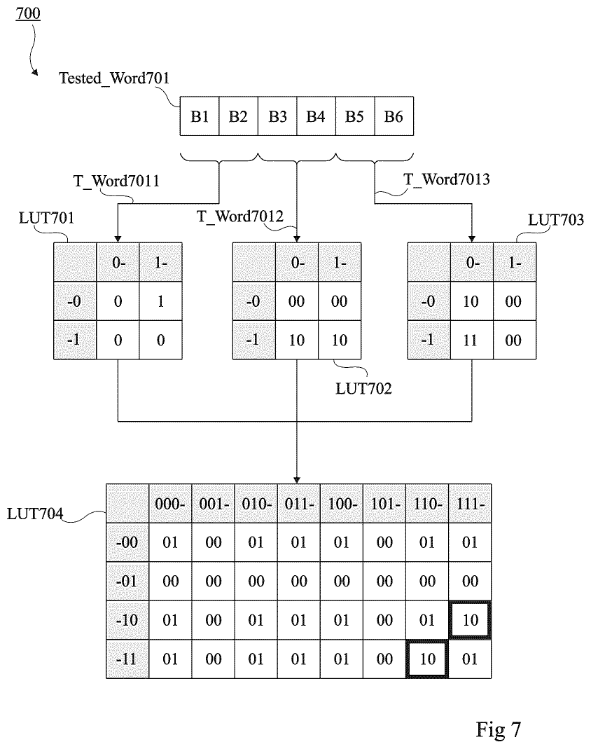

Each value Aj[p; q] indicates whether the comparison is a success or a failure. According to an example, value Aj[p; q] is represented by a binary data item comprising at least one bit. According to an embodiment, when test 200 compares the data word to be tested Tested_Word with a plurality of reference data words Ref_Words, the value Aj[p; q] may take distinct values to differentiate the comparison of a portion T_Wordj with the corresponding portions of different reference words Ref_Words. This concept is described in more detail with the practical example of FIG. 7.

At the end of the first comparison step, each primary lookup table LUTj outputs the value Aj[p; q] corresponding to the portion T_Wordj of the data word to be tested Tested_Word.

Then, a second comparison step is implemented by using the final lookup table F_LUT, which receives values A1[p; q] to AJ[p; q] supplied by primary lookup tables LUT1 to LUTJ. According to an example, the binary data forming values A1[p; q] to AJ[p; q] are concatenated into a data word T_WordF. The size of the final lookup table F_LUT depends on the total number of bits of the data word T_WordF. Practical examples of the final lookup table F_LUT are detailed in relation with FIGS. 4 to 7.

The final lookup table F_LUT stores values F[pf; qf], pf being an integer representing the index of the column of the value and qf being an integer representing the index of the row of the value. Values F[pf; qf] represent the result of the comparison of data word T_WordF with reference words Ref_Words. According to an example, when test 200 compares the data word to be tested Tested_Word with a plurality of reference data words Ref_Words, value Fj[p; q] make take different values to distinguish, if necessary, the different reference words Ref_Words.

As a summary, the method 300 for implementing test 200 for comparing the data word to be tested Tested_Word with one or a plurality of reference data words Ref_Words, comprises the following successive steps:
dividing the data word to be tested Tested_Word into the J portions T_Word1 to T_WordJ;
comparing each of the portions T_Word1 to T_WordJ of the data word to be tested Tested_Word with a corresponding portions of the reference data words Ref_Words, by using, for each comparison, one of lookup tables LUT1 to LUTJ;
compare the results of each of lookup tables LUT1 to LUTJ, by using the final lookup table F_LUT.

An advantage of method 300 is that it enables to implement test 200 by making it more resistant to side-channel attacks, and in particular to fault injection attacks. Indeed, during such an attack, it is possible to locally modify a data word. If the targeted data word is the or the one of the reference words Ref_Words, the test may be implemented, since the primary lookup tables LUT1 to LUTJ have previously been generated. If the targeted data word is a value of one of the primary or secondary lookup tables, it is more difficult to find a data word effectively modifying the operation of test 200.

FIG. 4 illustrates a practical example 400 of the method 300 of implementation of the test 200 described in relation with FIG. 2.

In the example of FIG. 4, the test carried out is the verification of the equality between the data word to be tested Tested_Word401 and a reference data word equal to 1011. The data word to be tested Tested_Word401 thus comprises four bits B1, B2, B3, and B4.

In the example of FIG. 4, it has been decided to divide the data word to be tested Tested_Word401 into a portion T_Word4011 comprising bits B1 and B2, and a portion T_Word4012 comprising bits B3 and B4.

To implement the first comparison step, method 400 uses two lookup tables LUT401 and LUT402.

Lookup table LUT401 receives as an input portion T_Word4011 and compares it with bits 10. It has been arbitrarily chosen that when portion T_Word4011 is equal to 10, the output data item of lookup table LUT401 is binary value 01, and that when portion T_Word4011 is different from 10, the output data item of lookup table LUT401 is binary value 10.

Lookup table LUT402 receives portion T_Word4012 as an input and compares it with bits 11. It has been arbitrarily chosen that when portion T_Word4012 is equal to 11, the output data item of lookup table LUT402 is binary value 10, and that when portion T_Word4012 is different from 11, the output data item of lookup table LUT402 is binary value 00.

As described hereabove, lookup tables LUT401 and LUT402 deliver as an output the values corresponding to the comparisons of portions T_Word4011 and T_Word4012 with data 10 and 11 to a final lookup table LUT403. According to an example, the output values of lookup tables LUT401 and LUT402 are concatenated into a data word T_WordF401.

In the example illustrated in FIG. 4, test 200 is only verified if data word T_WordF401 is equal to 0110. Thus, the final lookup table LUT403 compares data word T_WordF401 with bits 0110. It has been arbitrarily chosen that when data word T_WordF401 is equal to 0110, the output data item of lookup table LUT403 is binary value 1111, and that when data word T_WordF401 is equal to 0100, 1000, or 1010, the output data item of lookup table LUT401 is binary value 1010, indicating that test 200 has not been verified. It is not possible for data word T_WordF401 to be equal to the other values proposed by lookup table LUT403, it has thus been arbitrarily chosen that when data word T_WordF401 is equal to one of these values, the output data item of lookup table LUT403 is binary value 0000. Binary value 0000 thus indicates that the test has not executed correctly, and may for example allow the detection of an attack.

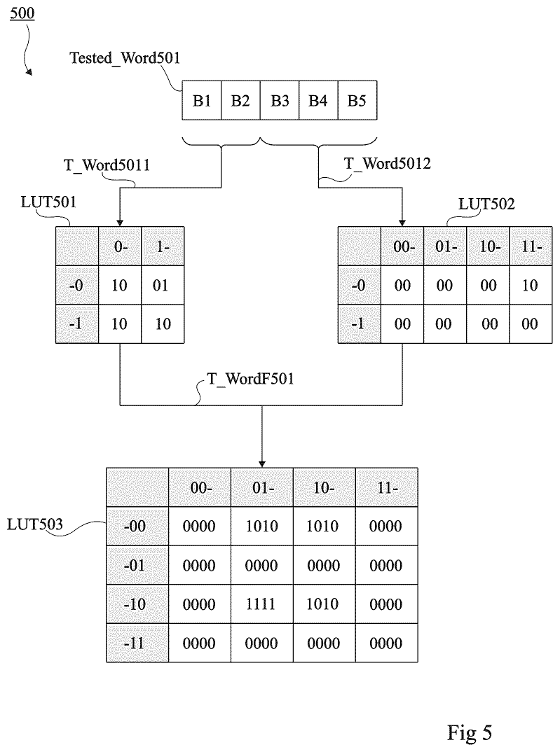

FIG. 5 illustrates a practical example 500 of the method 300 of implementation of the test 200 described in relation with FIG. 2. FIG. 5 illustrates, in particular, the case of the division of the data word to be tested into portions of different size.

In the example of FIG. 5, the test carried out is the verification of the equality between the data word to be tested Tested_Word501 and a reference data word equal to 10110. The data word to be tested Tested_Word501 thus comprises five bits B1, B2, B3, B4, and B5.

In the example of FIG. 5, it has been decided to divide the data word to be tested Tested_Word501 into a portion T_Word5011 comprising bits B1 and B2, and a portion T_Word5012 comprising bits B3, B4, and B5.

To implement the first comparison step, method 500 uses two lookup tables, LUT501 and LUT502.

Lookup table LUT501 receives portion T_Word5011 as an input and compares it with bits 10. It has been arbitrarily chosen that when portion T_Word5011 is equal to 10, the output data item of lookup table LUT501 is binary value 01, and that when portion T_Word5011 is different from 10, the output data item of lookup table LUT501 is binary value 10.

Lookup table LUT502 receives as an input portion T_Word5012 and compares it with bits 110. It has been arbitrarily chosen that when portion T_Word5012 is equal to 110, the output data item of lookup table LUT502 is binary value 10, and that when portion T_Word5012 is different from 110, the output data item of lookup table LUT502 is binary value 00.

As described hereabove, lookup tables LUT501 and LUT502 deliver as an output the values corresponding to the comparisons of portions T_Word5011 and T_Word5012 with data 10 and 110 to a final lookup table LUT503. According to an example, the output values of lookup tables LUT501 and LUT502 are concatenated into a data word T_WordF501.

In the example illustrated in FIG. 5, test 200 is only verified if data word T_WordF501 is equal to 0110, so the final lookup table LUT503 compares data word T_WordF501 with bits 0110. It has been arbitrarily chosen that when data word T_WordF501 is equal to 0110, the output data item of lookup table LUT503 is binary value 1111, and that when data word T_WordF501 is equal to 0100, 1000, or 1010, the output data item of lookup table LUT501 is binary value 1010, which indicates that test 200 is not verified. As previously, it is not possible for data word T_WordF501 to be equal to the other values provided by lookup table LUT503, it has thus been arbitrarily chosen that when data word T_WordF501 is equal to one of these values, the output data item of lookup table LUT503 is binary value 0000. Binary value 0000 thus indicates that the test has not been executed correctly, and may for example allow the detection of an attack.

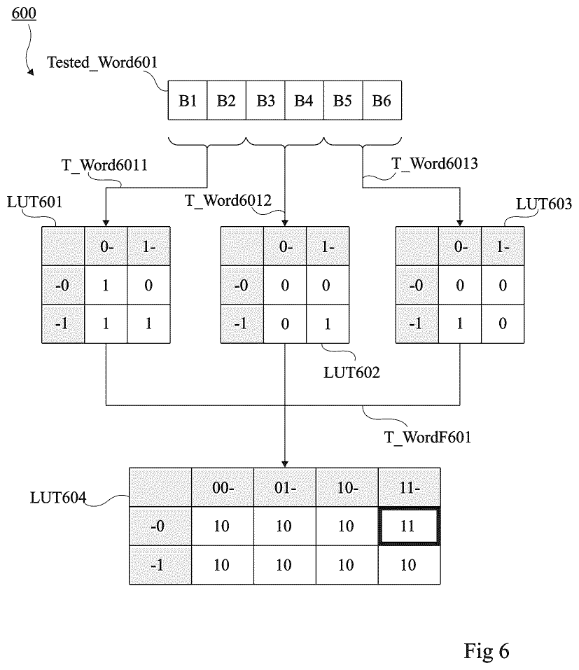

FIG. 6 illustrates a practical example 600 of the method 300 of implementation of the test 200 described in relation with FIG. 2. FIG. 5 illustrates, in particular, the case of the division of the data word to be tested into more than two portions.

In the example of FIG. 6, the test carried out is the verification of the equality between the data word to be tested Tested_Word601 and a reference data word equal to 101101. The data word to be tested Tested_Word601 thus comprises six bits B1, B2, B3, B4, B5, and B6.

In the example of FIG. 6, it has been decided to divide the data word to be tested Tested_Word601 into a portion T_Word6011 comprising bits B1 and B2, into a portion T_Word6012 comprising bits B3 and B4, and into a portion T_Word6013 comprising bits B5 and B6.

To implement the first comparison step, method 600 uses three lookup tables LUT601, LUT602, and LUT603.

Lookup table LUT601 receives as an input portion T_Word6011 and compares it with bits 10. It has been arbitrarily chosen that when portion T_Word6011 is equal to 10, the output data item of lookup table LUT601 is binary value 0, and that when portion T_Word6011 is different from 10, the output data item of lookup table LUT601 is binary value 1.

Lookup table LUT602 receives, as an input, portion T_Word6012 and compares it with bits 11. It has been arbitrarily chosen that when portion T_Word6012 is equal to 11, the output data item of lookup table LUT602 is binary value 1, and that when portion T_Word6012 is different from 11, the output data item of lookup table LUT602 is binary value 0.

Lookup table LUT603 receives, as input, portion T_Word6013 and compares it with bits 01. It has been arbitrarily chosen that when portion T_Word6013 is equal to 01, the output data item of lookup table LUT603 is binary value 1, and that when portion T_Word6013 is different from 01, the output data item of lookup table LUT603 is binary value 0.

As previously described, lookup tables LUT601, LUT602, and LUT603 deliver as an output the values corresponding to the comparisons of portions T_Word6011, T_Word6012, and T_Word6013 with data 10, 11, and 01 to a final lookup table LUT604. According to an example, the output values of lookup tables LUT601, LUT602, and LUT603 are concatenated into a data word T_WordF601.

In the example illustrated in FIG. 6, test 200 is only verified if data word T_WordF601 is equal to 011. Thus, the final lookup table LUT604 compares data word T_WordF601 with bits 011. It has been arbitrarily chosen that when data word T_WordF601 is equal to 011, the output data item of lookup table LUT604 is binary value 11, and that when data word T_WordF601 is different from 011, the output data item of lookup table LUT601 is binary value 10, which indicates that test 200 is not verified.

FIG. 7 illustrates a practical example 700 of the method 300 of implementation of the test 200 described in relation with FIG. 2. FIG. 5 illustrates, in particular, the case of the comparison of the data word with a plurality of reference data words.

In the example of FIG. 7, the test carried out is the verification of the equality between the data word to be tested Tested_Word701 and a reference data word equal to 101101 or a reference data word equal to 100100. The data word to be tested Tested_Word701 thus comprises six bits B1, B2, B3, B4, B5, and B6.

In the example of FIG. 7, it has been decided to divide the data word to be tested Tested_Word701 into a portion T_Word7011 comprising bits B1 and B2, into a portion T_Word7012 comprising bits B3 and B4, and into a portion T_Word7013 comprising bits B5 and B6.

To implement the first comparison step, method 700 uses three lookup tables LUT701, LUT702, and LUT703.

Lookup table LUT701 receives, as an input, portion T_Word7011 and compares it with bits 10. It has been arbitrarily chosen that when portion T_Word7011 is equal to 10, the output data item of lookup table LUT701 is binary value 1, and that when portion T_Word7011 is different from 10, the output data item of lookup table LUT701 is binary value 0.

Lookup table LUT702 receives as an input portion T_Word7012 and compares it with bits 11 or 01. It has been arbitrarily chosen that when portion T_Word7012 is equal to 11, the output of lookup table LUT702 is binary value 10, and that when portion T_Word7012 is equal to 01, the output of lookup table LUT702 is binary value 11. Further, when portion T_Word7012 is different from 11 and 01, the output data item of lookup table LUT702 is binary value 00.

Lookup table LUT703 receives portion T_Word7013 as an input and compares it with bits 01 or 00. It has been arbitrarily chosen that when portion T_Word7013 is equal to 01, the output of lookup table LUT703 is binary value 11, and that when portion T_Word7013 is equal to 00, the output of lookup table LUT703 is binary value 10. Further, when portion T_Word7013 is different from 01 and 00, the output of lookup table LUT703 is binary value 00.

As previously described, lookup tables LUT701, LUT702, and LUT703 deliver as an output the values corresponding to the comparisons of portions T_Word7011, T_Word7012, and T_Word7013 with data 10, 11, and 01 or 10, 01, and 00 to a final lookup table LUT704. According to an example, the output values of lookup tables LUT701, LUT702 and LUT703 are concatenated into a data word T_WordF701.

In the example illustrated in FIG. 7, test 200 is verified if data word T_WordF701 is equal to 11110 or to 11011. Thus, the final lookup table LUT704 compares the data word T_WordF701 with bits 11110 and 11011. It has been arbitrarily chosen that when data word T_WordF701 is equal to 11110 or to 11011, the output data item of lookup table LUT704 is binary value 10, and that when data word T_WordF701 is different from 11110 and 11011, the output data item of lookup table LUT701 is binary value 01, which indicates that test 200 is not verified. As previously, it is not possible for data word T_WordF701 to be equal to the other values provided by lookup table LUT704, it has thus been arbitrarily chosen that when data word T_WordF701 is equal to one of these values, the output data item of lookup table LUT703 is binary value 00. Binary value 00 thus indicates that the test has not been carried out correctly, and may for example allow the detection of an attack.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of implementation of a test of comparison of a first data word with at least one second data word, comprising:
dividing the first data word into at least one portion;
comparing each of the at least one portion of the first data word with at least one corresponding portion of the at least one second data word by using, for each comparison, a first lookup table; and
comparing one or more results from comparing each of the at least one portion of the first data word with at least one corresponding portion of the at least one second data word by using a second lookup table.

2. The method of claim 1, wherein during dividing, the first data word is divided into at least one portion.

3. The method of claim 1, wherein each result of the first lookup tables is a third binary word.

4. The method of claim 3, wherein the third binary word comprises a bit.

5. The method of claim 3, wherein the third binary word comprises at least two bits.

6. The method of claim 1, wherein each of the at least one portion of the first data word comprises at least two bits; and
each of the at least one corresponding portion of the at least one second data word comprises at least two bits.

7. The method of claim 1, wherein the test is selected from a group comprising: a logic equality test, a logic “greater than”-type test, a logic “greater than or equal to”-type test, a logic “less than”-type test, a logic “less than or equal to”-type test, a logic “is between”-type test, a test of a divisibility of an integer by another integer, a logic test concerning a Hamming weight of a binary data item, and any combination of one or a plurality of these above tests with one another.

8. The method of claim 1, wherein the one or more results from comparing each of the at least one portion of the first data word with at least one corresponding portion of the at least one second data word are concatenated into a fourth data word to be compared by using the second lookup table.

9. An electronic device adapted to implementing a test of comparison of a first data word with at least one second data word, comprising:
dividing the first data word into at least one portion;
comparing each of the at least one portion of the first data word with at least one corresponding portion of the at least one second data word, by using, for each comparison, a first lookup table; and
comparing one or more results from comparing each of the at least one portion of the first data word with at least one corresponding portion of the at least one second data word by using a second lookup table.

10. The electronic device of claim 9, wherein during dividing, the first data word is divided into at least one portion.

11. The electronic device of claim 9, wherein each result of the first lookup tables is a third binary word.

12. The electronic device of claim 11, wherein the third binary word comprises a bit.

13. The electronic device of claim 11, wherein the third binary word comprises at least two bits.

14. The electronic device of claim 9, wherein each of the at least one portion of the first data word comprises at least two bits; and
each of the at least one corresponding portion of the at least one second data word comprises at least two bits.

15. The electronic device of claim 9, wherein the test is selected from a group comprising: a logic equality test, a logic “greater than”-type test, a logic “greater than or equal to”-type test, a logic “less than”-type test, a logic “less than or equal to”-type test, a logic “is between”-type test, a test of a divisibility of an integer by another integer, a logic test concerning a Hamming weight of a binary data item, and any combination of one or a plurality of these above tests with one another.

16. The electronic device of claim 9, wherein one or more results from comparing each of the at least one portion of the first data word with at least one corresponding portion of the at least one second data word are concatenated into a fourth data word to be compared by using the second lookup table.
